(19) United States
(12) Patent Application Publication
(10) Pub. No.: US 2024/0202412 A1
(43) Pub. Date: Jun. 20, 2024

(54) MANUFACTURING METHOD OF AN ELECTRONIC DEVICE

(71) Applicant: Renesas Electronics Corporation, Tokyo (JP)

(72) Inventors: Atsushi UEMURA, Tokyo (JP); Kazuo OTOGE, Tokyo (JP); Nobuyuki ITO, Tokyo (JP)

(21) Appl. No.: 18/544,167

(22) Filed: Dec. 18, 2023

(30) Foreign Application Priority Data
Dec. 19, 2022 (JP) 2022-201921

(51) Int. Cl. G06F 30/367; G06F 30/392

(52) U.S. Cl. CPC G06F 30/367; G06F 30/392

(57) ABSTRACT

Accuracy of an EMI simulation is improved. A manufacturing method of an electronic device is a manufacturing method of an electronic device including a substrate and a semiconductor device mounted on the substrate. The manufacturing method of the electronic device includes a step (a) of preparing a power supply model including impedance information on a power supply path included in the electronic device, a step (b) of measuring a power supply noise at the time of operation of the electronic device, a step (c) of calculating a power supply current inside the semiconductor device, based on the power supply noise and the power supply model, and a step (d) of simulating EMI (Electro Magnetic Interference) characteristics, based on the power supply current and the power supply model.

### CROSS-REFERENCE TO RELATED APPLICATION

The disclosure of Japanese Patent Application No. 2022-201921 filed on Dec. 19, 2022, including the specification, drawings and abstract is incorporated herein by reference in its entirety.

### BACKGROUND

The present invention relates to a manufacturing method of an electronic device.

There is disclosed techniques listed below.

[Patent Document 1] Japanese Unexamined Patent Application Publication No. 2014-026599

EMI (Electro Magnetic Interference) regulations have become severe in recent years. Under such severe EMI regulations, many person-hours and/or high cost are necessary for commercializing an electronic device using an IC. The Patent Document 1 discloses a technique of optimizing the EMI by using a simulation to analyze a power supply current of an LSI.

### SUMMARY

It is important to take an EMI countermeasure in consideration of a mechanism causing the EMI. In the EMI, an IC (Integrated Circuit) consumes current, and the IC becomes a source of noise. The noise propagates through a propagation path (for example, a package, a printed circuit board) , and is emitted from an antenna (for example, a signal line, a power supply/GND pattern, a harness).

Therefore, it is necessary to perform an EMI simulation using a power supply current (also referred to as an in-IC power supply current) inside the IC. However, the time required for the simulation increases with a higher degree of integration of the IC, and the simulation needs to be performed again for every change of a program installed in the IC.

Other objects and novel characteristics will be apparent from the description of the present specification and the accompanying drawings.

According to an embodiment, a manufacturing method of an electronic device is a manufacturing method of an electronic device including a substrate and a semiconductor device mounted on the substrate. The manufacturing method of the electronic device includes a step (a) of preparing a power supply model including impedance information on a power supply path included in the electronic device. And, the method includes a step (b) of measuring a power supply noise on the substrate at time of operation of the electronic device. And, the method includes a step (c) of calculating a power supply current inside the semiconductor device, based on the power supply noise and the power supply model. And, the method includes a step (d) of simulating EMI (Electro Magnetic Interference) characteristics, based on the power supply current and the power supply model.

According to the above embodiment, accuracy of the EMI simulation can be improved.

### BRIEF DESCRIPTIONS OF THE DRAWINGS

FIG. 1 is a diagram illustrating a procedure of a manufacturing method according to a related art.

FIG. 2 is an explanatory diagram illustrating an overview of a manufacturing method according to a first embodiment.

FIG. 3 is an explanatory diagram illustrating a procedure of the manufacturing method according to the first embodiment.

FIG. 4 is an explanatory diagram illustrating an IC power supply model and a PCB power supply model according to the first embodiment.

FIG. 5 is an explanatory diagram illustrating a transmission parameter according to the first embodiment.

FIG. 6 is an explanatory diagram illustrating details of a method of calculating an in-IC power supply current according to the first embodiment.

### DETAILED DESCRIPTION

For making the explanation clear, the following descriptions and the drawings may be appropriately omitted or simplified. In addition, each of components shown in the drawings as functional blocks that perform various processes may be made of a CPU, a memory, and/or any other circuits in terms of hardware, or may be achieved by a program loaded in a memory etc., in terms of software. Accordingly, it is understood by those skilled in the art that these functional blocks can be achieved in various forms by hardware alone, software alone, or a combination thereof, and the achievement is not limited to any of them. In each drawing, the same elements are denoted with the same symbol, and the repetitive explanations thereof are omitted as appropriate.

The program described above includes a command group (or software code) used to make a computer perform one or more functions described in the embodiments when the command (or software code) is loaded into the computer. The program may be stored in a non-transitory computer readable medium or a tangible storage medium. As examples but not limited thereto, the computer readable medium or tangible storage medium includes random-access memory (RAM), read-only memory (ROM), flash memory, solid-state drive (SSD), or other memory techniques, CD-ROM, digital versatile disc (DVD), Blu-ray (registered trademark) disc, or other optical disc storage, magnetic cassette, magnetic tape, magnetic disk storage, or other magnetic storage device. The program may be transmitted on a transitory computer readable medium or communication medium. As examples but not limited thereto, the transitory computer readable medium or communication medium includes electrical, optical, acoustic, or other form of propagation signals.

### Background Leading to Embodiment

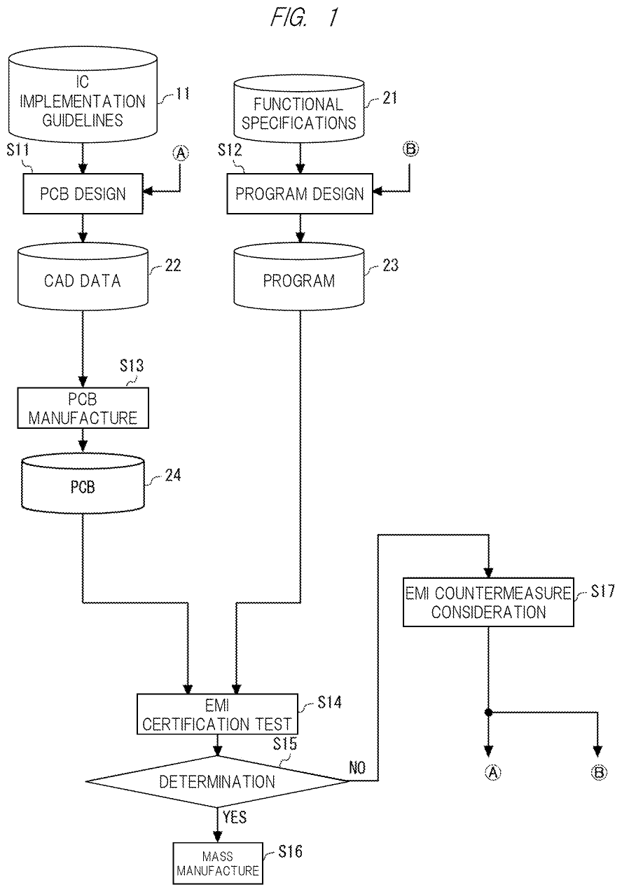

First, a problem newly found by the present inventor will be described with reference to FIG. 1. FIG. 1 is an explanatory diagram illustrating a procedure of a related-art manufacturing method of an electronic device. The electronic device is, for example, an ECU (Electronic Control Unit). The electronic device includes a PCB (Printed Circuit Board) and an IC mounted on the PCB. The IC is also referred to as a semiconductor device. The

IC is a microcontroller IC storing a program. The IC includes a semiconductor chip and a package. On the PCB, a power supply IC that supplies power to the microcontroller IC may further be mounted. The PCB is also referred to as a substrate.

It is assumed that implementation guidelines 11 for the IC to be mounted on the PCB and functional specifications 21 for the electronic device have already been prepared. The IC means a package on which the semiconductor chip is mounted. The implementation guidelines 11 may be prepared by a manufacturer X who manufactures the IC, and the function specifications 21 may be prepared by a manufacturer Y who manufactures the electronic device.

At step S11, the manufacturer Y designs the PCB based on the implementation guidelines 11. In this manner, CAD data 22 of the PCB is prepared. At step S12, the manufacturer Y designs the program 23 based on the functional specifications 21.

At step S13, the manufacturer Y manufactures the PCB 24 based on the CAD data 22. The manufacturer Y writes the program 23 into the IC mounted on the PCB 24, and performs an EMI certification test at step S14. At step S15, the manufacturer Y determines whether or not the EMI certification test is passed. If the EMI certification test is passed, the manufacturer Y manufactures the electronic devices in mass quantities at step S16.

If the EMI certification test is not passed, the manufacturer Y considers an EMI countermeasure at step S17. The EMI countermeasure is to modify a layout of the PCB 24, add an EMI countermeasure component (for example, a chip capacitor) to the PCB 24, and modify the program 23. In addition, to shield a component (for example, a signal line) to be an antenna may be also considered. In accordance with a result of the consideration at step S17, the manufacturer performs step S11 or S12.

According to the related art, accuracy of estimation of an in-IC power supply current is low, and therefore, accuracy of an EMI simulation is also low. Therefore, the manufacturing method of the electronic device shown in FIG. 1 does not include the step of performing the EMI simulation.

If the EMI certification test is not passed, trial manufacture of the PCB and the EMI certification test need to be repeated. Therefore, it is difficult to previously estimate a development period for the electronic device, and a risk of delay of timing for shipment of the electronic device is high. In addition, it is difficult to select an effective EMI countermeasure component, and therefore, a large number of EMI countermeasure components are possibly mounted on the PCB. This case increases the manufacturing cost of the electronic device. The present inventor of the present application has thought up embodiments based on the above-described studies. The embodiments will be described below.

### First Embodiment

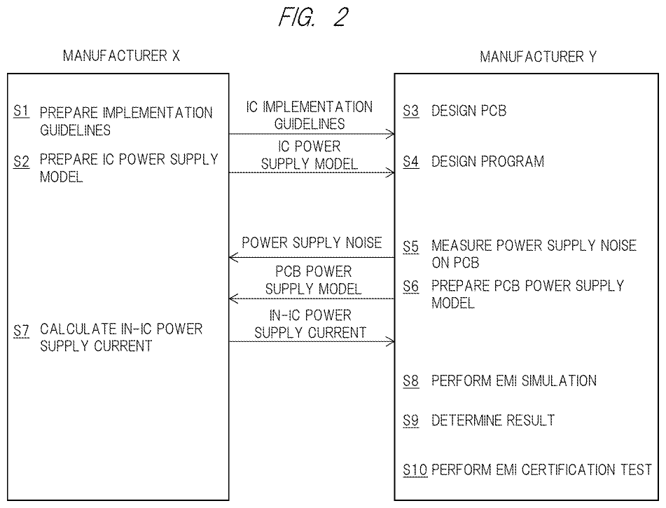

FIG. 2 is an explanatory diagram illustrating an overview of a manufacturing method of an electronic device according to a first embodiment. The manufacturer X manufactures the IC that is the semiconductor device. The manufacturer Y manufactures the electronic device (for example, the ECU) . At least some steps performed by the manufacturer X in FIG. 2 may be performed by the manufacturer Y. Similarly, at least some steps performed by the manufacturer Y may be performed by the manufacturer X. In addition, the manufacturer X and the manufacturer Y may be the same manufacturer.

Step S1 is the step of preparing the implementation guidelines 11 in FIG. 1. Step S3 corresponds to step S11 in FIG. 1. Step S4 corresponds to step S12 in FIG. 1. Step S10 corresponds to step S14 in FIG. 1. Steps S2, S5, S6, S7, S8, and S9 represent steps added to the related art.

At step S1, the manufacturer X prepares the implementation guidelines for the IC to be mounted on the PCB. The manufacturer X passes the implementation guidelines to the manufacturer Y.

The implementation guidelines are used at step S3. A plurality of ICs may be mounted on the PCB.

At step S2, the manufacturer X prepares the power supply model (referred to as IC power supply model) of the power supply path inside the IC. The IC power supply model includes impedance information on the power supply path inside the IC. The manufacturer passes the IC power supply model to the manufacturer Y. The IC power supply model is used at steps S7 and S8. Note that a specific example of the IC power supply model will be described later.

At step S3, the manufacturer Y designs the PCB based on the implementation guidelines prepared at step S1. At step S4, the manufacturer Y designs the program written into the IC. At step S5, the manufacturer Y measures the power supply noise on the PCB at the time of operation of the electronic device. The manufacturer Y passes a waveform of the power supply noise on the PCB to the manufacturer Y. The waveform of the power supply noise on the PCB is also referred to as on-PCB power supply voltage. The on-PCB power supply voltage is used at step S7.

At step S6, from design data (CAD data) of the PCB, the manufacturer Y extracts the PCB power supply model that is a modeled power supply path on the PCB. The PCB power supply model includes impedance information on the power supply path on the PCB. The manufacturer Y passes the PCB power supply model to the manufacturer X. The PCB power supply model is used at step S7.

At step S7, from the on-PCB power supply voltage, the IC power supply model and the PCB power supply model, the manufacturer X calculates the power supply current (the in-IC power supply current) inside the IC. The manufacturer X passes the in-IC power supply current to the manufacturer Y. The in-IC power supply current is used at step S8.

At step S8, the manufacturer Y performs the EMI characteristic simulation for simulating the EMI certification test, based on the in-IC power supply current, the IC power supply model and the PCB power supply model. At step S9, the manufacturer Y determines a result of the simulation.

If the result of the simulation does not pass the standards, the manufacturer Y considers the EMI countermeasure. In accordance with a result of the consideration, the manufacturer

Y performs the PCB design of step S3 or the program design of step S4.

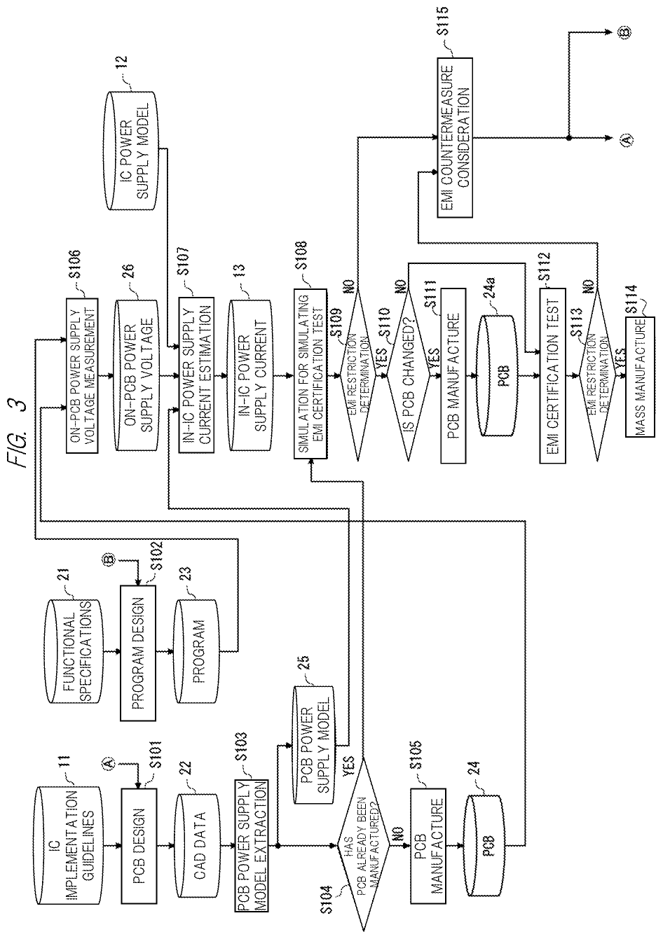

On the other hand, if the result of the simulation passes the standards, the manufacturer Y performs the EMI certification test at step S10. If the EMI certification test is passed, the manufacturer Y manufactures the electronic device in mass quantities. If the EMI certification test is not passed, the manufacturer Y considers whether to take the EMI countermeasure, and performs the PCB design of step S3 or the program design of step S4 in accordance with a result of the consideration. FIG. 3 is an explanatory diagram illustrating a procedure of the manufacturing method according to the first embodiment. It is assumed that the implementation guidelines 11, the functional specifications 21, and the IC power supply model 12 have already been prepared. The implementation guidelines 11 is prepared at step S1 in FIG. 2. The IC power supply model 12 is prepared at step S2 in FIG. 2.

At step S101, the manufacturer Y designs a PCB based on the implementation guidelines 11. In this manner, the CAD data 22 of the PCB is prepared. Step S101 corresponds to step S3 in FIG. 2. In addition, at step S102, the manufacturer Y designs the program 23 based on the functional specifications 21. Step S102 corresponds to step S4 in FIG. 2.

At step S103, the manufacturer Y extracts the PCB power supply model 25 from the CAD data 22. Step S103 corresponds to step S6 in FIG. 2.

At step S104, the manufacturer Y determines whether or not the PCB has already been manufactured. If the PCB has already been manufactured, the manufacturer Y performs step S108. If the PCB has not yet been manufactured, the manufacturer Y manufactures a PCB 24 at step S105.

At step S106, the manufacturer Y writes the program 23 into the IC mounted on the PCB 24, operates it, and measures the on-PCB power supply noise that is the on-PCB power supply voltage 26. Step S106 corresponds to step S5 in FIG. 2.

At step S107, the manufacturer X estimates the in-IC power supply current 13 based on the PCB power supply model 25, the on-PCB power supply voltage 26 and the IC power supply model 12. Step S107 corresponds to step S7 in FIG. 2. Details of step S107 that is step S7 will be described later.

At step S108, the manufacturer Y performs the simulation for simulating the EMI certification test, based on the in-IC power supply current 13. Step S108 corresponds to step S8 in FIG. 2. At step S109, the manufacturer Y determines whether or not a result of the simulation passes EMI restrictions. Step S109 corresponds to step S9 in FIG. 2. If the result of the simulation does not pass the EMI restrictions, the manufacturer Y considers the EMI countermeasure at step S115, and performs step S101 or S102 in accordance with a result of the consideration. Then, if both steps S101 and S102 or only step S102 is performed, steps S106, S107 and S108 are performed again. If only step S101 is performed, step S108 is performed again.

If the result of the simulation passes the EMI restrictions, the manufacturer Y determines at step S110 whether or not the design of the PCB 24 is to be changed. If the design of the PCB 24 is to be changed, the manufacturer Y manufactures a new PCB 24a at step S111. Then, the manufacturer Y performs the EMI certification test using the PCB 24a at step S112. On the other hand, if the design of the PCB 24 is not to be changed, the manufacturer Y performs the EMI certification test using the PCB 24 at step S112.

At step S113, the manufacturer Y determines whether or not the EMI certification test is passed. If the EMI certification test is passed, the manufacturer Y manufactures the electronic devices in mass quantities at step S114. On the other hand, if the EMI certification test is not passed, the manufacturer Y performs step S115.

In the manufacturing method according to the related art, the EMI certification test is performed after the PCB design and the program design, and the EMI countermeasure is taken if any problem is found. On the other hand, in the manufacturing method according to the first embodiment, the in-IC power supply current at the time of operation of the program designed for each electronic device is calculated. Therefore, the simulation for simulating the EMI certification test can be performed with high manufacturing accuracy, and therefore, resources and/or resources for the EMI certification test can be saved.

Next, a method of calculating the in-IC power supply current will be described in detail. The in-IC power supply current is calculated through first and second steps. The first step is the step of calculating the in-IC power supply voltage. The second step is the step of calculating the in-IC power supply current from the in-IC power supply voltage.

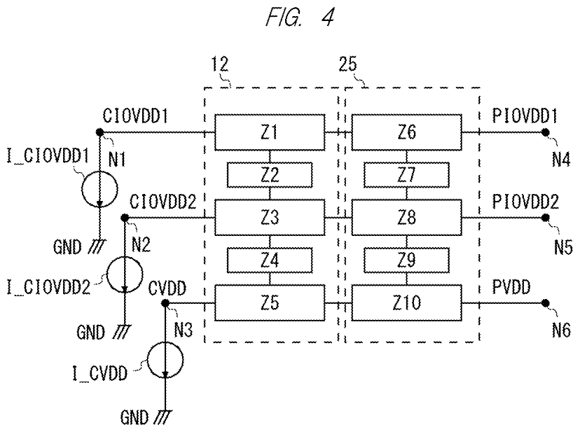

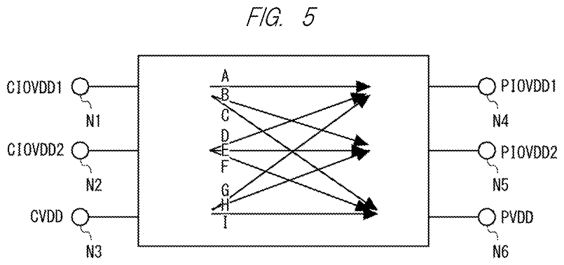

The first step will be described with reference to FIGS. 4 and 5. FIG. 4 is an explanatory diagram illustrating the IC power supply model and the PCB power supply model. It is assumed that three types of power supplies are supplied to the IC. At step S5 in FIG. 2, it is assumed that a plurality of the on-PCB power supply voltages are measured at the same time meaning the same phase.

Nodes N1, N2, and N3 represent nodes at each of which the in-IC power supply voltage is calculated. Nodes N4, N5, and N6 represent nodes at each of which the power supply voltage is measured on the PCB.

The power supply voltages at the nodes N1, N2, and N3 are CIOVDD 1, CIOVDD2, and CVDD, respectively. The power supplyvoltages at the nodes N4, N5, and N6 are PIOVDD1, PIOVDD2, and PVDD, respectively. A reference sign I_CIOVDD1 represents a current flowing from the node N1 to a ground GND. A reference sign I_CIOVDD2 represents a current flowing from the node N2 to the ground GND. A reference sign I_CVDD represents a current flowing from the node N3 to the ground GND.

It is assumed that the in-IC power supply voltage CIOVDD1 does not include noise propagated from the nodes N2 and N3. It is assumed that the in-IC power supply voltage CIOVDD2 does not include noise propagated from the nodes N1 and N3. It is assumed that the in-IC power supply voltage CVDD does not include noise propagated from the nodes N1 and N2.

The IC power supply model 12 includes impedances Z1 to Z5. The PCB power supply model 25 includes impedance Z6 to Z10. The impedances Z1 and Z6 are connected in series between the nodes N1 and N4. The impedances Z3 and Z8 are connected in series between the nodes N2 and N5. The impedances Z5 and Z10 are connected in series between the nodes N3 and N6. The impedance Z2 is connected to the impedances Z1 and Z3. The impedance Z4 is connected to the impedances Z3 and Z5. The impedance Z7 is connected to the impedances Z6 and Z8. The impedance Z9 is connected to the impedances Z8 and Z10. Note that the respective configurations of the IC power supply model 12 and the PCB power supply model 25 are not limited to the configurations shown in FIG. 4.

The in-IC power supply voltages CIOVDD1, CIOVDD2, and CVDD are calculated based on transmission parameters. FIG. 5 is an explanatory diagram illustrating the transmission parameters. The transmission parameters A to I represent relations between the in-IC power supply voltages CIOVDD1, CIOVDD2, and CVDD and the on-PCB power supply voltages PIOVDD1, PIOVDD2, and PVDD. For example, the transmission parameter A represents a ratio of the in-IC power supply voltage CIOVDD1 to the on-PCB power supply voltage PIOVDD1 obtained when a current of 1 A is applied to the node N1. Therefore, the transmission parameters A to I can be calculated from the IC power supply model 12 and the PCB power supply model 25.

The following formula (1) represents a formula for calculating the on-PCB power supply voltage PIOVDD1 from the in-IC power supply voltages CIOVDD1, CIOVDD2, and CVDD.

$$[ Formula 1 ]$$

$$CIOVDD 1 \times A + CIOVDD 2 \times D + CVDD \times G = PIOVDD 1 \qquad ( 1 )$$

The following formula (2) represents a formula for calculating the on-PCB power supply voltage PIOVDD2 from the in-IC power supply voltages CIOVDD1, CIOVDD2, and CVDD.

$$[ Formula 2 ]$$

$$CIOVDD 1 \times B + CIOVDD 2 \times E + CVDD \times H = PIOVDD 2 \qquad ( 2 )$$

The following formula (3) represents a formula for calculating the on-PCB power supply voltage PVDD from the in-IC power supply voltages CIOVDD1, CIOVDD2, and CVDD.

$$[ Formula 3 ]$$

$$CIOVDD 1 \times C + CIOVDD 2 \times F + CVVDD \times I = PVDD \qquad ( 3 )$$

The formulae (1) to (3) are expressed using a matrix as shown in the following formula (4) . Therefore, the in-IC power supply voltages CIOVDD1, CIOVDD2, and CVDD can be calculated using an inverse matrix as shown in the following formula (5) .

$$[ Formula 4 ]$$

$$( \begin{matrix}A & D & G \\ B & E & H \\ C & F & I\end{matrix} ) ( \begin{matrix}CIOVDD 1 \\ CIOVDD 2 \\ CVDD\end{matrix} ) = ( \begin{matrix}PIOVDD 1 \\ PIOVDD 2 \\ PVDD\end{matrix} ) \qquad ( 4 )$$

$$[ Formula 5 ]$$

$$( \begin{matrix}CIOVDD 1 \\ CIOVDD 2 \\ CVDD\end{matrix} ) = {( \begin{matrix}A & D & G \\ B & E & H \\ C & F & I\end{matrix} )}^{- 1} ( \begin{matrix}PIOVDD 1 \\ PIOVDD 2 \\ PVDD\end{matrix} ) \qquad ( 5 )$$

Next, the second step will be described. At the second step, the in-IC power supply current is calculated based on the in-IC power supply voltages CIOVDD1, CIOVDD2, and CVDD. This is because the in-IC power supply current is required in order to simulate the EMI characteristics of the electronic device. In order to calculate the in-IC power supply current, an input impedance inside the IC is required in addition to the in-IC power supply voltage. The input impedance inside the IC is calculated from a ratio of the in-IC power supply voltage to the in-IC power supply current. In addition, the input impedance inside the IC may be calculated when the transmission parameters are calculated. The input impedance is expressed using an amplitude and a phase.

The following formula (6) represents a formula for calculating the in-IC power supply current I_COVDD1 from the in-IC power supply voltage CIOVDD1. An impedance Z_CIOVDD1 represents a ratio of the in-IC power supply current I_CIOVDD1 to the in-IC power supply voltage CIOVDD1. The impedance Z_CIOVDD1 can be calculated from the IC power supply model 12 and the PCB power supply model 25. The impedance Z_CIOVDD1 may also be calculated as the in-IC power supply voltage CIOVDD1 obtained when a current of 1A is applied to the node N1.

$$[ Formula 6 ]$$

$$I\_CIOVDD 1 = CIOVDD 1 \div Z\_CIOVDD 1 \qquad ( 6 )$$

The following formula (7) represents a formula for calculating the in-IC power supply current I_CIOVDD2 from the in-IC power supply voltage CIOVDD2. An impedance Z_CIOVDD2 represents a ratio of the in-IC power supply current I_CIOVDD2 to the in-IC power supply voltage CIOVDD2. The impedance Z_CIOVDD2 can be calculated from the IC power supply model 12 and the PCB power supply model 25. The impedance Z_CIOVDD2 may also be calculated as the in-IC power supply voltage CIOVDD2 obtained when a current of 1A is applied to the node N2.

$$[ Formula 7 ]$$

$$I\_CIOVDD 2 = CIOVDD 2 \div Z\_CIOVDD 2 \qquad ( 7 )$$

The following formula (8) represents a formula for calculating the in-IC power supply current I_CVDD from the in-IC power supply voltage CVDD. An impedance Z_CVDD represents a ratio of the in-IC power supply current I_CVDD to the in-IC power supply voltage CVDD. The impedance Z_CVDD can be calculated from the IC power supply model 12 and the PCB power supply model 25. The impedance Z_CVDD may also be calculated as the in-IC power supply voltage CVDD obtained when a current of 1A is applied to the node N3.

$$[ Formula 8 ]$$

$$I\_CVDD = CVDD \div Z\_CVDD \qquad ( 8 )$$

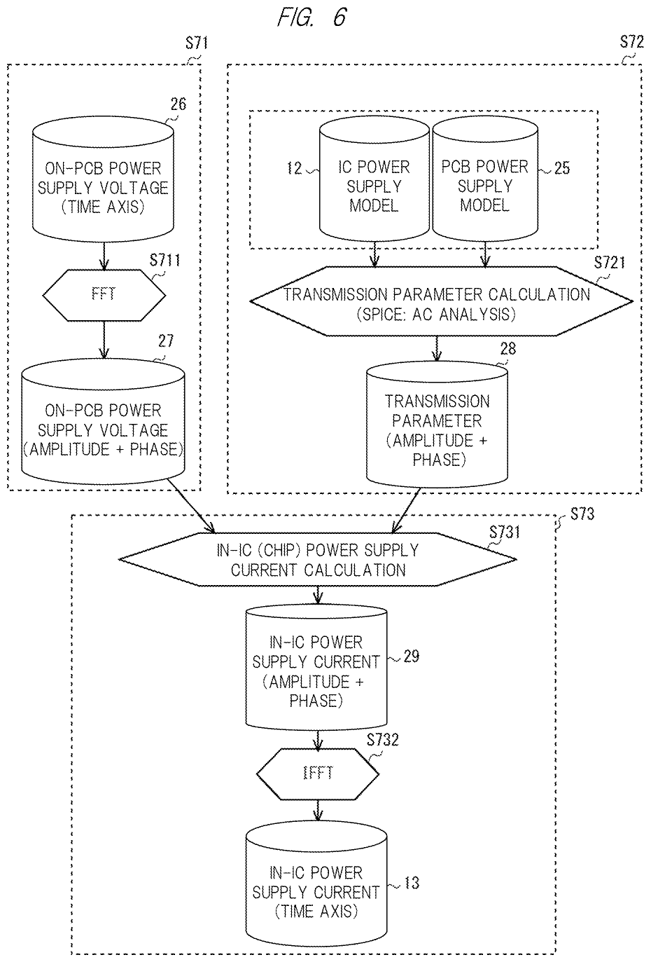

Next, details of a procedure of the method of calculating the in-IC power supply current will be described with reference to FIG. 6. The in-IC power supply current is calculated through steps S71, S72, and S73. Steps S71, S72, and S73 may be included in step S7 in FIG. 2 that is step S107 in FIG. 3.

Step S71 includes step S711. It is assumed that the on-PCB power supply voltage 26 has already been measured. The on-PCB power supply voltage 26 may be measured by using an oscilloscope and probing a power supply terminal on the PCB. A plurality of the on-PCB power supply voltages 26 may be measured at the same time by a trigger function of the oscilloscope. The on-PCB power supply voltage 26 represents voltage data on a time axis. At step S711, the on-PCB power supply voltage 26 is subjected to FFT (Fast Fourier Transform). In this manner, the on-PCB power supply voltage 27 is prepared. The on-PCB power supply voltage 27 includes amplitude data and phase data on a frequency axis.

Next, step S72 will be described. Step S72 includes step S721. It is assumed that the IC power supply model 12 and the PCB power supply model 25 have already been prepared. At step S721, the transmission parameter 28 between the semiconductor chip included in the IC and the PCB is calculated based on the IC power supply model 12 and the PCB power supply model 25. The transmission parameter 28 represents a ratio of the in-IC power supply voltage to the on-PCB power supply voltage. Therefore, the transmission parameter represents a rate of noise propagation from a node inside the IC to a node on the PCB. The node on the PCB is a node at which the on-PCB power supply voltage has been measured. The transmission parameter 28 is calculated by an AC analysis of SPICE. The transmission parameter 28 includes amplitude data and phase data on the frequency axis.

Next, step S73 will be described. Step S73 includes steps S731 and S732. At step S731, the in-IC power supply current 29 is calculated based on the on-PCB power supply voltage 27 and the transmission parameter 28. The in-IC power supply current 29 includes amplitude data and phase data on the frequency axis. At step S732, the in-IC power supply current 29 is subjected to IFFT (Inverse Fast Fourier Transform). In this manner, the in-IC power supply current 13 is calculated. The in-IC power supply current 13 represents power supply current data on the time axis.

The process shown in FIG. 6 may be performed by a computer including a processor and a memory. The processor may be, for example, a microprocessor, an MPU (Micro Processing Unit), or a CPU. The processor may include a plurality of processors. The memory is made of a volatile memory and a non-volatile memory. The memory may include a plurality of physically independent memory devices. The volatile memory may be, for example, an SRAM (Static RAM) or a DRAM (Dynamic RAM), an EEPROM (Electrically Erasable Programmable ROM), a flash memory, or a hard disk drive, or any combination thereof. The memory may include a storage disposed apart from the processor. The memory may store one or more software modules (computer programs) including a command group and data for performing the processes through steps S71, S72, and S73. In some implementations, the processor reads out the software module from the memory, and executes it.

Finally, effects produced by the first embodiment will be described. In the first embodiment, the in-IC power supply current is accurately calculated from the power supply noise measured on the PCB. Then, in the first embodiment, the EMI simulation analysis using the accurate power supply current is incorporated into a flow for developing the electronic device such as ECU. Since wasteful trial manufacture of the electronic device is eliminated, the development period for the electronic device is shortened. In addition, since selection of the effective noise countermeasure component is assisted, the manufacturing cost of the electronic device is saved.

In the foregoing, the invention made by the inventors of the present invention has been concretely described on the basis of the embodiments. However, it is needless to say that the present invention is not limited to the foregoing embodiments, and various modifications can be made within the scope of the present invention.

What is claimed is:

1. A manufacturing method of an electronic device including a substrate and a semiconductor device mounded on the substrate, the manufacturing method comprising steps of:
(a) preparing a power supply model including impedance information on a power supply path included in the electronic device;
(b) measuring a power supply noise on the substrate at time of operation of the electronic device;
(c) calculating a power supply current inside the semiconductor device, based on the power supply noise and the power supply model; and
(d) simulating EMI (Electro Magnetic Interference) characteristics, based on the power supply current and the power supply model.

2. The manufacturing method of the electronic device according to claim 1,
wherein the step (a) includes steps of:
(e) preparing a power supply model including impedance information on a power supply path inside the semiconductor device; and
(f) preparing a power supply model including impedance information on a power supply path on the substrate.

3. The manufacturing method of the electronic device according to claim 1,
wherein the steps (b), (c) and (d) are performed again after a design of the electronic device is changed based on a result of simulating the EMI characteristics at the step (d).

4. The manufacturing method of the electronic device according to claim 3, further comprising a step of :
(g) changing the design of the electronic device by changing a program to be written into the semiconductor device.

5. The manufacturing method of the electronic device according to claim 1,
wherein the steps (a) and (d) are performed again after a design of the electronic device is changed based on a result of simulating the EMI characteristics at the step (d) .

6. The manufacturing method of the electronic device according to claim 5, further comprising a step of:
(g) changing the design of the electronic device by changing a layout of the semiconductor device.

7. The manufacturing method of the electronic device according to claim 1,
wherein the steps (a), (b), (c) and (d) are performed again after a design of the electronic device is changed based on a result of simulating the EMI characteristics at the step (d) .

8. The manufacturing method of the electronic device according to claim 7, further comprising a step of :
(g) changing the design of the electronic device by changing a program to be written into the semiconductor device and a layout of the semiconductor device.

9. The manufacturing method of the electronic device according to claim 1,
wherein, at the step (b) of measuring the power supply noise, power supply noises of a plurality of power supplies are measured at the same phase.

10. The manufacturing method of the electronic device according to claim 1,
wherein, at the step (c) of calculating the power supply current inside the semiconductor device, a transmission parameter is prepared based on the power supply model, and the power supply current inside the semiconductor device is calculated based on the transmission parameter.

11. The manufacturing method of the electronic device according to claim 10,
wherein the transmission parameter includes amplitude data and phase data on a frequency axis.

12. The manufacturing method of the electronic device according to claim 10,
wherein, at the step (c) of calculating the power supply current inside the semiconductor device, a power supply voltage inside the semiconductor device is calculated based on the transmission parameter, and the power supply current inside the semiconductor device is calculated based on the power supply voltage inside the semiconductor device and the power supply model.
